(19) United States
(12) Patent Application Publication
(10) Pub. No.: US 2011/0317364 A1
(43) Pub. Date: Dec. 29, 2011

(54) SYSTEM AND METHOD FOR COOLING AN ELECTRONIC DEVICE

(76) Inventors: Mark S. Tracy, Tomball, TX (US); Earl W. Moore, Cypress, TX (US)

(21) Appl. No.: 13/255,629

(22) PCT Filed: Apr. 14, 2009
(86) PCT No.: PCT/US09/40494

§ 371 Date: Sep. 9, 2011

(51) Int. Cl. H05K 7/20

(52) U.S. Cl. 361/696

(57) ABSTRACT

An exemplary embodiment of the present invention provides a system for cooling an electronic device. The system includes a plenum disposed adjacent to an interior surface of a housing for the electronic device, wherein the plenum is placed between a heat generating component and the interior surface of the housing, and wherein the plenum reduces heat transfer from the heat generating component to an exterior surface of the housing. The system also includes a fan configured to create an airflow in the plenum.

### BACKGROUND

Cooling of electronic components in computer systems is often challenging due to the close proximity and high heat output of many components, such as processors and video controllers. Further, due to the compact size of portable computers, cooling components may be especially challenging. In addition to controlling the temperature of the components, controlling the temperature of the exterior of a portable computer, for example, the lower surface, is useful for end user comfort.

### BRIEF DESCRIPTION OF THE DRAWINGS

Certain exemplary embodiments are described in the following detailed description and in reference to the drawings, in which:

FIG. 1 is a drawing of a user holding a portable computer;

FIG. 2 is an exploded drawing of a portable computer having a plenum, in accordance with an exemplary embodiment of the present invention;

FIG. 3 is a drawing of a bottom housing section of a portable computer case, showing the plenum, in accordance with an exemplary embodiment of the present invention;

FIG. 4 is a cut-away view of the plenum illustrating a airflow out of the fan, in accordance with an exemplary embodiment of the present invention;

FIG. 5 is a cross-section view of the plenum of FIG. 5, in accordance with an exemplary embodiment of the present invention;

FIG. 6 is a cross-section view of the plenum illustrating an airflow into the plenum from the fan, in accordance with an exemplary embodiment of the present invention; and

FIG. 7 is a flow chart of a method for cooling a portable computer, in accordance with an exemplary embodiment of the present invention.

### DETAILED DESCRIPTION OF SPECIFIC EMBODIMENTS

An exemplary embodiment of the present invention provides a cooling mechanism for an electronic device that can substantially isolate the heat generating components in the electronic device from a heat sensitive surface, for example, a lap holding a portable computer. The cooling mechanism uses a fan to force an airflow through a thin chamber, or plenum, located between the heat generating components and the heat sensitive surface.

Heat may be transferred from the heat generating components into the plenum by conduction, for example, if the plenum is made from a metal, such as aluminum. Heat may also be removed from the heat generating components by openings in the plenum that are proximate to the heat generating components. Such openings can facilitate the removal of heat from the heat generating components by enhancing an airflow over the components. The airflow may then be directed into the plenum, to be exhausted through the fan. In another exemplary embodiment of the present invention, the fan may direct air into the plenum, creating an airflow out of the openings in the plenum, over the heat generating components and out openings in the housing of the portable computer.

In an exemplary embodiment of the present invention, the electronic device is a portable computer. In other exemplary embodiments, the electronic device may be a power supply, a rack-mounted computer, a desktop computer, a DVD ROM, a CD ROM, a Blu-Ray Player, a cable television decoder box, and the like.

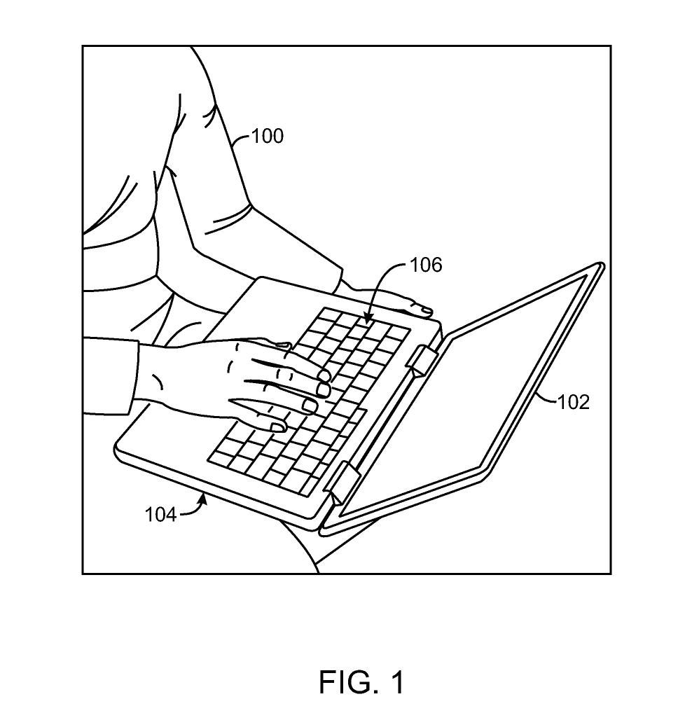

FIG. 1 is a drawing of a user 100 holding a portable computer 102 in his or her lap 104. Generally, many of the components of the portable computer 102 may be located in proximity to the lower surface of the portable computer 102, for example, below the keyboard 106. The heat from both the user 102 and the components may cause the portable computer 102 to overheat, leading to a thermal shutdown or even damage to vulnerable components. Further, the heat generated on the lower surface of the portable computer 102 may be uncomfortable for the user. Numerous other situations may also lead to overheating of the portable computer 102, for example, setting the computer on the hood of a car or a soft surface during use.

In an exemplary embodiment of the present invention, the heat may be removed from the portable computer by a plenum placed between the heat generating components and the lower surface of the computer. The plenum may, for example, be a thin, hollow structure mounted to the inside surface of the lower housing of the portable computer. An airflow may be directed through the plenum to exhaust heat from the unit. In other exemplary embodiments, a plenum may be used to protect components in other types of installations from heat damage caused by proximate heat sources. For example, a thin, hollow plenum may be located along a surface of a rack-mounted device, to protect the components of the rack-mounted device from nearby heat sources, such as other devices in the rack.

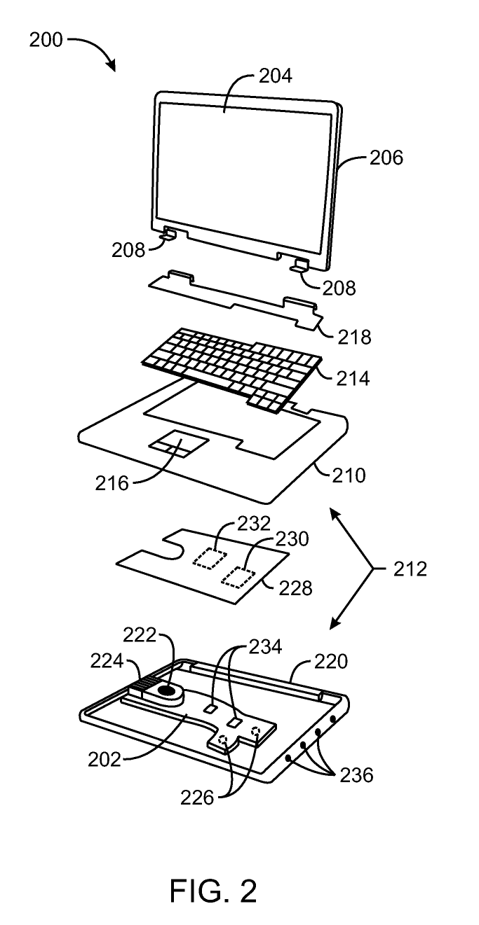

FIG. 2 is an exploded view of a portable computer 200 showing a plenum 202, in accordance with an exemplary embodiment of the present invention. In the exploded view, a flat screen display 204 is enclosed in an upper housing 206 of the portable computer 200. Hinges 208, on the lower portion of the upper housing 206, are configured to mount to an upper section 210 of a lower housing 212. A keyboard 214 may generally be mounted in the upper section 210, along with a pointing device 216. The hinges 208 may be hidden under an upper cover 218 after being mounted to the upper section 210.

The lower housing 212 also has a lower section 220, which may include the plenum 202. The plenum 202 may be coupled to a fan 222, which may be configured to exhaust air from the plenum 202 through openings 224 in the side of the lower section 220. Other openings 226, for example, in the lower surface of the lower section 220 may allow air to enter the plenum 202 from outside the portable computer 200. In another exemplary embodiment of the present invention, the fan 222 may be configured to draw air into the portable computer 200 from the openings 224. In this embodiment, air is directed into the plenum 202 by the fan 222 and out through the openings 226 in the lower surface of the lower section 220.

A circuit board 228 may be mounted over the plenum 202 in the lower section 220, along with other components, such as hard drives, connectors, and the like. The circuit board 228 may have mounted components that generate heat, for example, a processor 230 or a video controller 232, and the like. The circuit board 228 may be mounted with the components 230 and 232 facing the plenum 202 to improve heat flow from the components 230 and 232 into the plenum 202. Furthermore, the plenum 202 may be made from a heat conductive metal, such as aluminum. The components 230 and 232 may be mounted in direct contact with the plenum 202 to conduct heat from the components 230 and 232. Heat exchangers, including remote heat exchangers and heat pipes, may be mounted to the components 230 and 232 to conduct heat into the plenum 202 for removal from the unit.

In another exemplary embodiment of the present invention, openings 234 in the plenum 202 may be made proximate to the mounted positions of the components 230 and 232 to allow air flow around the components 230 and 232, or around heat exchangers mounted to the components 230 and 232. If the fan 222 is configured to exhaust air from the plenum 202, ventilation openings 236 may be made in the lower housing 212 to allow air to be drawn into the lower housing 212. The air drawn into the lower housing 212 may then be circulated around the components 230 and 232, prior to being exhausted from the lower housing 212 through the plenum 202. Similarly, if the fan 222 is, configured to direct air into the plenum 202, the openings 234 may allow the airflow from the plenum 202 to circulate over the components 230 and 232, prior to leaving the case through the ventilation openings 236.

In an exemplary embodiment of the present invention, the plenum 202 may extend across the entire lower section 220, with openings in the sides of the lower section 220 to allow air to flow into or out of the plenum 202. This configuration may be useful for allowing ventilation even if the lower surface of the lower section 220 is obstructed, for example, when the portable computer 200 is placed on a soft surface.

The thickness of the plenum 202 may be selected to fit in a limited space inside the lower housing 212. In an exemplary embodiment of the present invention, the plenum 202 may be less than about 0.25 cm in thickness from the upper interior surface to the lower interior surface. In other exemplary embodiments the plenum 202 may be less than about 0.1 cm in thickness, 0.5 cm in thickness, or any other appropriate thickness.

The width of the plenum 202 may generally be greater than the thickness of the plenum 202. The width of the plenum 202 may be selected on the basis of airflow and the location of heat generating components. For example, a plenum 202 with a low thickness may have a greater width to allow for greater total airflow. Further, the width of the plenum 202 may be selected to extend across a number of widely spaced heat generating components, such as the processor 230 and the video controller 232. In an exemplary embodiment of the present invention, the width of the plenum 202 may be greater than about 5 cm. In other exemplary embodiments, the width of the plenum 202 may be greater than about 1 cm, 3 cm, 7 cm, 10 cm, or any other appropriate width.

In an exemplary embodiment of the present invention the plenum 202 may be substantially flat. For example, the ratio of the width of the plenum 202 to the thickness of the plenum 202 may be greater than about three to one. In other exemplary embodiments, the ratio of the width to the thickness may be 3 to 1, 4 to 1, 10 to 1, 15 to 1, 20 to 1, or any other appropriate ratio, for example, for incorporation into a limited space within a computing device.

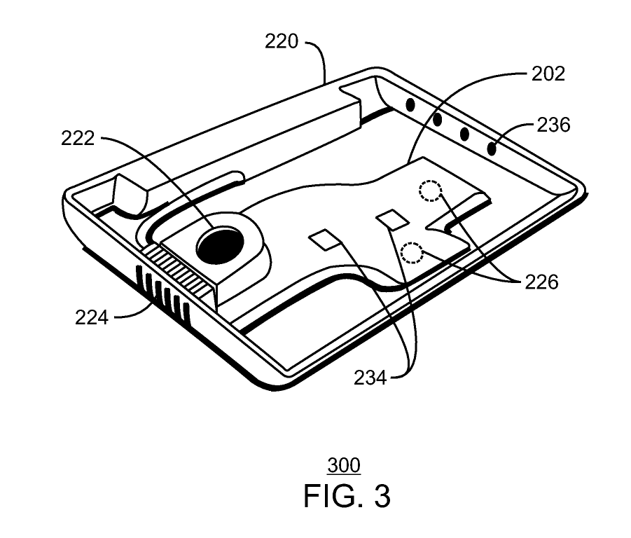

FIG. 3 is a enlarged view 300 of the lower section 220, showing the plenum 202, in accordance with an exemplary embodiment of the present invention. The fan 222 is illustrated as a single unit in this view 300. In other exemplary embodiments of the present invention, the fan 222 may include two or more fans, for example, mounted at each end Of the plenum 202. Further, the fan 222 may be a tube fan, an axial fan, a blower fan, or any other suitable type of device for moving air in a small space.

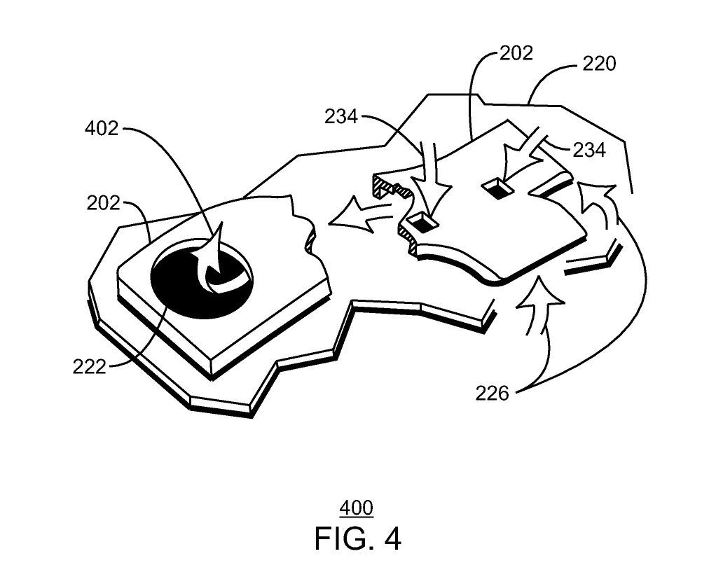

FIG. 4 is a cut-away view 400 of the plenum 202 illustrating an airflow 402 out of the fan 222, in accordance with an exemplary embodiment of the present invention. The airflow 402 from the fan 222 may then be exhausted from the portable computer through openings that are operatively coupled to the fan 222. Air can be drawn into the plenum 202 through openings 226 in the bottom of the case. In other exemplary embodiments, the openings 226 may be positioned along the side of the portable computer. Other openings 234 may be used to pull air across heat generating components or across remote heat exchangers that are thermally coupled to the heat generating components.

As discussed above, in another exemplary embodiment of the present invention, the fan 222 may be configured to pressurize the plenum 202. This would reverse the airflows illustrated in FIG. 4, which may allow air to be directed onto heat generating components.

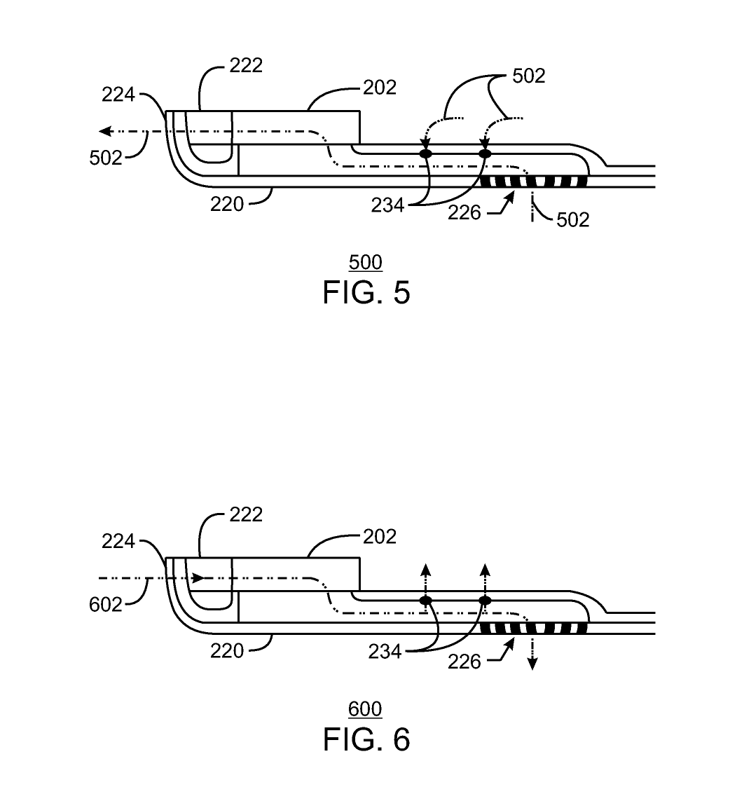

FIGS. 5 and 6 are cross-sectional views of the plenum 222, showing the exemplary air flow patterns that may be used in accordance with embodiments of the present invention. In the exemplary embodiment 500 illustrated in FIG. 5, air is exhausted from the plenum 202 by the fan 222 through an opening 224 in the side of the lower section 220 of the housing, creating an airflow 502. Air is drawn into the plenum 202 through openings 226, that can be located on the lower surface of the lower section 220 or which can be located on other sides of the lower section 220. As discussed previously, openings 234 on top of the plenum 202 may allow the airflow 502 to pass over the heat generating components and into the plenum 202. In the exemplary embodiment 600 shown in FIG. 6 the fan is configured to create an airflow 602 into the plenum 222, which may blow air across the heat generating components.

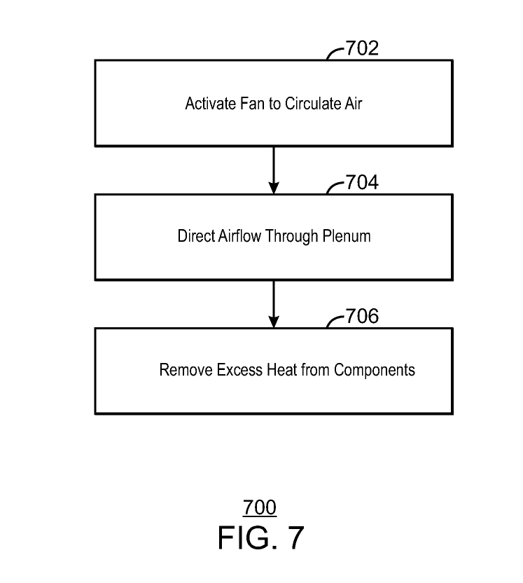

FIG. 7 is a flow chart of a method 700 for cooling a portable computer, in accordance with an exemplary embodiment of the present invention. The method begins at block 702 with the activation of a fan to circulate air through a plenum in a portable computer. The fan may be left running continuously when the portable computer is powered or deactivated to save power when not needed. For example, when the portable computer is running on batteries, the fan may be activated based on the temperature of the internal components. At block 704, an airflow is directed through the plenum, which can be located along an interior surface of a housing for a portable computer. In an exemplary embodiment of the present invention, the plenum is placed between heat generating components and a heat sensitive location. At block 706, excess heat is removed from the heat generating components by the airflow through the plenum. If the temperature drops to a predetermined set point, the fan may be deactivated to save energy.

What is claimed is:

1. A system for cooling an electronic device, comprising:
a plenum disposed adjacent to an interior surface of a housing for the electronic device, wherein the plenum is placed between a heat generating component and the interior surface of the housing, and wherein the plenum reduces heat transfer from the heat generating component to an exterior surface of the housing; and
a fan configured to create an airflow in the plenum.

2. The system of claim 1, wherein the plenum is located along a bottom interior surface of the housing, and wherein a ratio of a width of the plenum to a thickness of the plenum is greater than about 3 to 1.

3. The system of claim 1, comprising openings in the plenum in proximity to the heat generating component.

4. The system of claim 1, wherein the fan is configured to positively pressurize the plenum.

5. The system of claim 1, wherein the fan is configured to negatively pressurize the plenum.

6. The system of claim 1, comprising openings through a bottom surface of the housing into the plenum.

7. The system of claim 1, comprising openings through a side surface of the housing into the plenum.

8. The system of claim 1, comprising two or more fans operatively coupled to the plenum.

9. A method for cooling an electronic device, comprising:
directing an airflow through a plenum located along an interior surface of a housing for the electronic device, wherein the plenum is placed between a heat generating component and the interior surface, and wherein the plenum reduces heat transfer from the heat generating component to an exterior surface of the housing; and
removing heat from the heat generating components by the airflow.

10. The method of claim 9, comprising flowing air through openings in the plenum that are in proximity to the heat generating component.

11. The method of claim 9, comprising transferring heat from the heat generating component to the plenum through a heat exchanger that is thermally coupled to the heat generating component.

12. The method of claim 9, comprising pressurizing the plenum by forcing air from an air intake into the plenum.

13. The method of claim 9, comprising negatively pressurizing the plenum by exhausting air from the plenum.

14. The method of claim 9, comprising flowing air into or out of the plenum through openings in a bottom surface of the housing.

15. The method of claim 9, comprising flowing air into or out of the plenum through openings in a side surface of the housing.
